(19) United States
(12) Patent Application Publication
(10) Pub. No.: US 2006/0030069 A1
(43) Pub. Date: Feb. 9, 2006

(54) Packaging method for manufacturing substrates

(76) Inventor: Chien-Wei Chang, Yang-Mei Town (TW)

Correspondence Address: SUPREME PATENT SERVICES, P.O. BOX 2339, SARATOGA, CA, 95070-0339, US

(21) Appl. No.: 10/912,602

(22) Filed: Aug. 4, 2004

(51) Int. Cl. H01L 21/50

(52) U.S. Cl. 438/106

(57) ABSTRACT

A method for manufacturing IC substrate is provided, including using the bottom plating technique to form copper columns to elevate the bump pads in the micro opening to the surface level of the solder resist. The metal column can act as a stress buffer induced by the temperature profile during the IC packaging process. The metal column can also solve the problems of insufficient bonding strength to the bump pad and the inapplicable solder due to the printing technique restriction. The metal column elevates the bump pad to the surface level of the solder resist so that the under fill after bonding the chip can be performed more easily. The present invention can improve the yield rate and the density of the packaging and is suitable for the next generation, including nano-scale electronic products.

### FIELD OF THE INVENTION

The present invention relates to a method of semiconductor manufacturing process, and more particularly to a method for packaging the substrate in semiconductor manufacturing.

### BACKGROUND OF THE INVENTION

The recent product developments within the electronic industry are able to integrate more functions in a single substrate used in the electronic products, which results in the rapid increase in the number of I/Os required in the substrate. Therefore, the flip chip (FC) technologies are used to allow higher package density.

In addition, the new OEM technology employed in the wafer fabrication has also progressed from 0.18 μm scale to 0.13 μm scale, or even the nano-scale, such as 90 nm, or 65 nm. Accordingly, the bump pitch between the bump pads is reduced from the 200 μm scale to the 150 μm scale, or even 100 μm scale. At present, the increase of the alignment precision is still able to meet the requirement for 200 μm bump pitch. However, for the next generation electronic product, it is necessary to develop a newer packaging method to meet the 100 μm bump pitch requirement.

A conventional substrate includes a two- to eight-layer printed circuit board (PCB) made of ceramic or organic material. The interconnection among the layers are achieved by using mechanical or laser drilling to drill micro vias which are then wired to the bump pads for connecting the bump of the chips. Then, the solder resist is used for defining the bump pad area and the solder are applied. When the bump pitch is reduced from 200 μm to 100 μm, the routing between the bump pads will cause the opening of the defined bump pad area becoming too small. That is, the opening will be reduced rapidly from 100 μm to even smaller. The conventional photosensitive solder resist and the solder application techniques cannot cope with the aforementioned small size problem. There are two conventional methods for defining bump pad area. The first is called solder resist defined lands, and the second called metal defined lands. FIGS. 1 and 2 show the schematic view of the solder resist defined lands and the metal defined lands, respectively.

As shown in FIG. 1, because the width of bump pad 101 is too small (less than 60 μm), solder 102 cannot be printed into the opening to form firm contact with bump pad 101. The space between bump pad 101 and solder 102 implies the poor quality of the soldering.

As shown in FIG. 2, the bump pitch between two bump pads 201 is too small (less than 75 μm). As a result, solder resist 202b between two bump pads 201 is peeled off because the area of solder resist 202b is too small and the adhesion is not strong enough.

In addition, if the bump pad is not elevated to the level of the solder resist, the connection between the bump pad and the bump of the chip may not be strong enough because of the unsuccessful under-filling of the chip or insufficient solder volume during the packaging process. Therefore, the conventional packaging method is unable to manufacture the bump of the micro via on the substrate. It is necessary to improve the conventional packaging method to solve the problem posed by the restriction.

### SUMMARY OF THE INVENTION

The present invention provides a packaging method for manufacturing the substrate. The method uses the CCD precise alignment laser drill to open up the defined bump pad area, then uses bottom plating to form metal column, such as copper, to elevate the bump pads buried in the solder resist to the surface level of the solder resist, and applies surface processing, such as electroplating Ni/Au or Sn/Pb, to prevent oxidation. The metal column can act as a stress buffer induced by the temperature profile during the packaging process. The metal column can also solve the problems of insufficient bonding strength to the bump pad and the inapplicable solder due to the printing technique restriction. The metal column elevates the bump pad to the surface level of the solder resist so that the under-filling after the bonding the chip can be performed more easily. The present invention can improve the yield rate and the density of the packaging and is suitable for the next generation, including nano-scale electronic products.

### BRIEF DESCRIPTION OF THE DRAWINGS

FIG. 1 shows a schematic view of the solder resist defined lands.

FIG. 2 shows a schematic view of the metal defined lands.

FIGS. 3A-3V show a packaging method for substrates in accordance with the present invention.

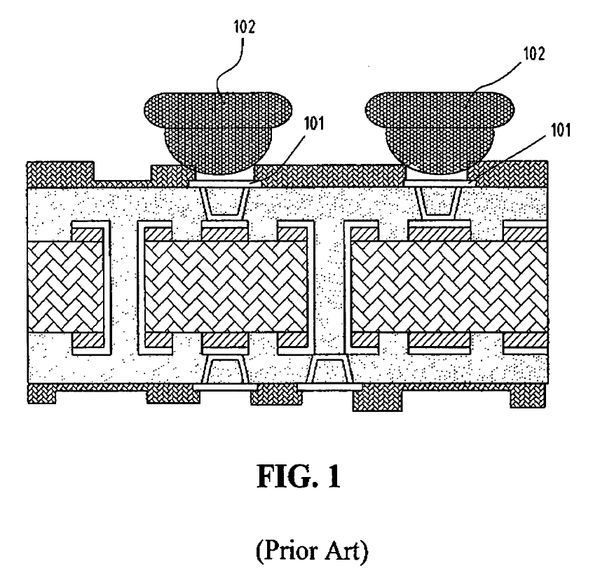

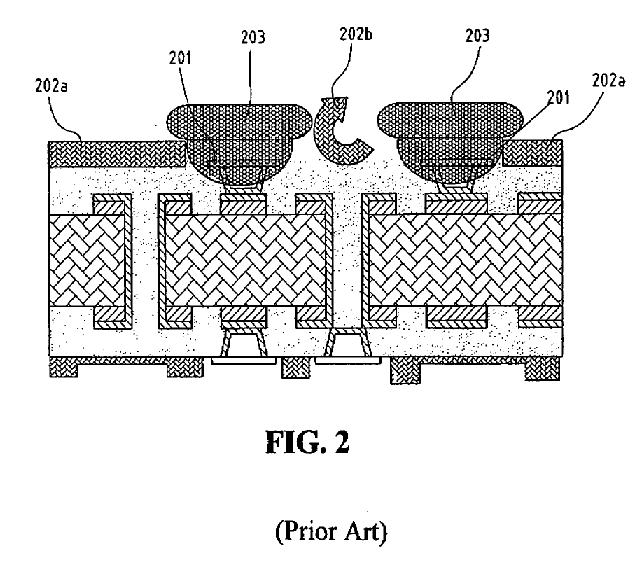

### DETAILED DESCRIPTION OF THE INVENTION

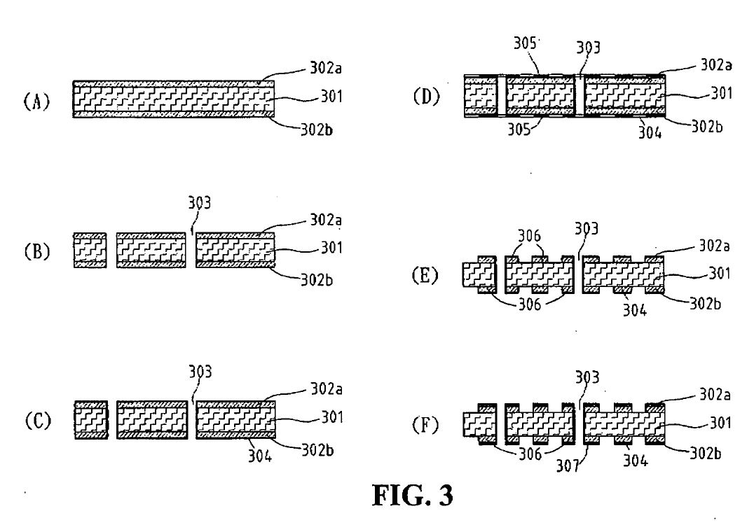

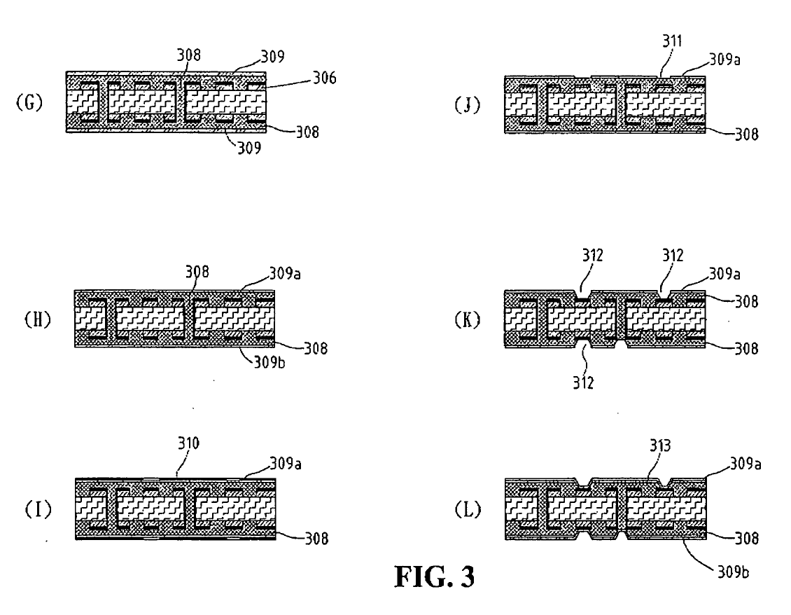

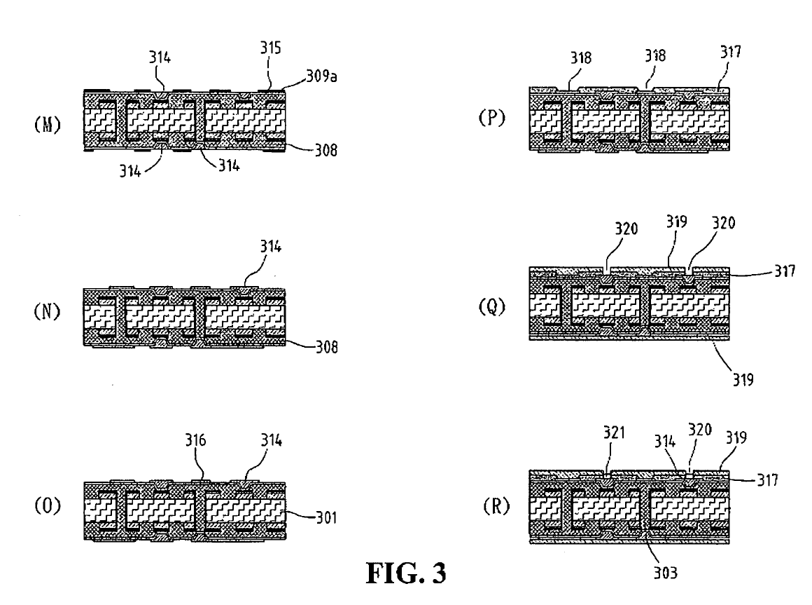

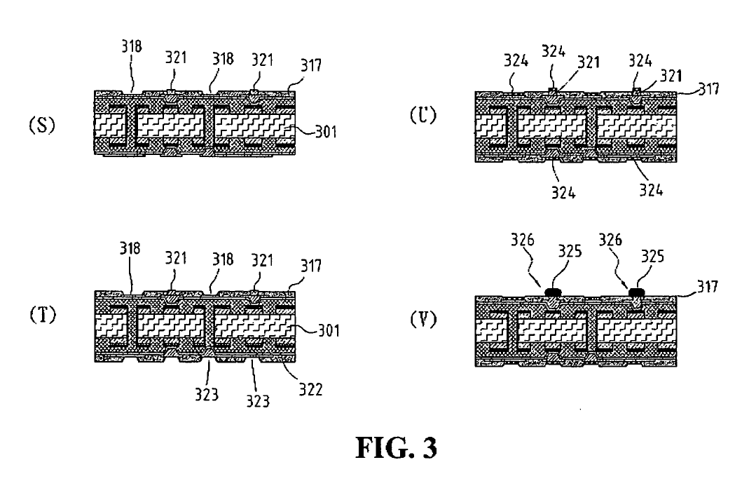

FIGS. 3A-3V show the steps of the method for manufacturing a high-density substrate, which include:

FIGS. 3A-3C show a process of providing a substrate. FIG. 3A shows a core 301 that may be a substrate made of Bismaleimide Triazing (BT), other organic materials, or even ceramics. A first metal layer 302a and 302b, which may be made of copper (Cu), is formed on substrate 301. FIG. 3B shows a plurality of through holes 303 drilled on core 301. FIG. 3C shows that a first metal plated layer 304, which may be made of copper (Cu), is formed on first metal layer 302a, 302b and through holes 303.

FIGS. 3D-3F show a step of forming an inner layer circuit. FIG. 3D uses a dry film 305 containing an image as the inner layer circuit. A part of the first metal plated layer 304 and the first metal layer 302a, 302b are etched to form traces 306. As shown in FIG. 3E, the remained portions of the first metal plated layer 304 and the first metal layer 302 are left as inner layer circuit 306. FIG. 3F shows that inner layer circuit 306 is oxidized to form a black oxide inner layer circuit 307.

FIGS. 3G-3H show a step of forming a dielectric layer 308 and a second metal layer 309. FIG. 3G shows using a dielectric material and a metal on traces 306 of the substrate to form dielectric layer 308 and the second metal layer 309. Dielectric layer 308 is made of Bismaleimide Triazing (BT) or other dielectric materials. The second metal layer 309 may be made of copper (Cu). FIG. 3H shows the second metal layer 309 is laminated to form the second metal layer 309a, 309b.

FIGS. 3I-3N show the step of forming vias in the dielectric layer. FIG. 3I shows a dry film 310 used as a laser conformal mask 311, as shown in FIG. 3J. A plurality of micro vias 312 is drilled on dielectric layer 308, as shown in FIG. 3K. A metal, such as copper, is electroplated in micro vias 312 to form a second plated metal 313, as shown in FIG. 3L. FIG. 3M shows a dry film 315 is used as a plating resist. Apply metal plated on the area exposed by the dry film image and plating filled copper 314 in vias 312, as FIG. 3N shows.

The steps up to this point can be repeated to from a plurality of inner circuit layers and dielectric layers with vias in the substrate.

FIG. 3O shows a step of forming a bump pad circuit layer. FIG. 3O shows the use of etching to form bump pad circuit layers 316. Bump pad circuit layer 316 on the top side of substrate 301 is the bump side, and bump pad circuit layer 316 on the bottom side of substrate 301 is the ball pad side.

FIGS. 3P-3Q show a step of forming a plurality of solder resist areas and packaging micro openings. A solder resist 317 is applied on bump pad circuit layer 316 to form a plurality of bump pads 318, as shown in FIG. 3P. FIG. 3Q shows plating resist 319 is applied onto solder resist 317. A plurality of micro openings 320 is formed by CCD aligned laser.

FIG. 3R shows a step of forming a plurality of metal columns by bottom plating on micro openings 320. The bottom plating technique uses micro openings 320 as cathode, and metal 314 of dielectric layer 312 and through holes 303 as electrical conductive path to deposit the metal ions, such as copper, of the electroplating solution onto micro openings 320 to form metal columns 321. The height of metal columns 321 are elevated to the surface level of plating resist 319.

FIG. 3S shows a step of surface processing. Plating resist 319 is stripped to expose solder resist 317. A thin metal fast etching technique is applied on both sides of substrate 301 to expose metal columns 321 and the circuit layers on both bump pad side and ball pad side.

FIG. 3T shows the step of forming a ball pad solder resist area. A solder resist 322 is applied onto the ball pad side to from a plurality of ball pads 323.

FIG. 3U shows the step of surface processing. The surface processing step, including depositing Ni/Au, Pb-free solder and organic protective film 324, is applied to metal columns 321, bump pads 318, and ball pads 323.

FIG. 3V shows the step of forming bumps. A solder 325 is transfer-printed to metal columns 321 to from bumps 326. Solder 325 may be Sn/Pb solder or Pb-free solder. Bumps 326 are flattened for better soldering.

While we have shown and described the embodiment in accordance with the present invention, it should be clear to those skilled in the art that further embodiments may be made without departing from the scope of the present invention.

1. A method for manufacturing IC substrate comprising the following steps:
providing a substrate having a bump pad circuit layer and a plurality of micro vias filled with a metal, said bump circuit layer being covered with a solder resist to form a plurality of bump pads, and a plurality of micro openings being formed through said solder resist above said micro vias: and
using bottom plating to form a plurality of metal columns in said micro openings on the metal of said micro vias so that the height of said metal columns is elevated to a surface level of said solder resist.

2. The method as claimed in claim 1, wherein said bottom plating uses micro openings as cathode, and the metal of said micro vias and metal plated on through holes formed through said substrate as electrical conductive path to deposit metal ions of an electroplating solution onto said micro openings to form said metal columns.

3. The method as claimed in claim 1, wherein said step of providing a substrate having a bump pad circuit layer further comprises the steps of:
forming a first metal layer and a plurality of through holes through said substrate, and forming a first plated metal layer on said first metal layer and said through holes;
forming an inner layer circuit by etching said first plated metal layer and said first metal layer to form trenches and traces for said inner layer circuit, said inner layer circuit being black-oxidized;
applying dielectric into said through holes and said trenches and covering entire said inner layer circuit to form a dielectric layer then forming a second metal layer on said dielectric layer; said second metal layer being laminated
forming micro vias in said dielectric layer, then forming a second plated metal layer in said micro vias, and filling said micro vias with a metal;
forming a bump pad circuit layer on top side of said substrate and a ball pad circuit layer on bottom side of said substrate by etching,
forming a plurality of bump pad areas by applying a solder resist on said bump pad circuit layer to form a plurality of bump pads; and
applying a plating resist onto said solder resist, said plurality of bump pads and said ball pad circuit layer.

4. The method as claimed in claim 3, wherein said bottom plating further comprises the steps of:
stripping said plating resist by thin metal fast etching on both sides of said substrate to expose said metal columns and said bump pad circuit layer and said ball pad circuit layer;
forming ball pad areas by applying a solder resist on said ball pad circuit layer;
performing, surface processing on said metal column and said bump pads; and
forming bumps by transfer-printing solder onto said metal column, and flattening said bumps.

5. The method as claimed in claim 3 further comprising repeating said steps of forming an inner layer circuit, a dielectric layer and a second metal layer, and micro vias in the dielectric layer in order to form a substrate structure of having a plurality of inner layer circuits and dielectric micro vias.

6. The method as claimed in claim 3, wherein said second plated metal layer is copper, and said metal columns are also copper.

7. The method as claimed in claim 1, wherein said substrate is made of organic material such as Bismalcimide Triazing (BT) or ceramic material.

8. The method as claimed in claim 1, wherein the height of said metal columns is elevated to a same surface level of said solder resist.

9. The method as claimed in claim 1, wherein the height of said metal columns is elevated to a level higher than said surface level of said solder resist.

10. The method as claimed in claim 1, wherein the height of said metal columns is elevated to a level slightly lower than said surface level of said solder resist.

11. The method as claimed in claim 2, wherein said first metal layer is made of copper.

12. The method as claimed in claim 2, wherein said first plated metal layer is made of copper.

13. The method as claimed in claim 2, wherein said second metal layer is made of copper.

14. The method as claimed in claim 2, wherein said second plated metal layer is made of copper.

15. The method as claimed in claim 2, wherein said metal used to fill said micro vias in said dielectric layer is made of copper.

16. The method as claimed in claim 4, wherein said solder used in transfer-printing is a Sn/Pb solder or Pb-free solder.

17. The method as claimed in claim 1, wherein said IC substrate is a flip chip substrate.
